(19) United States
(12) Patent Application Publication
(10) Pub. No.: US 2025/0060052 A1
(43) Pub. Date: Feb. 20, 2025

(54) RETAINER FOR A PORT OF AN ENCLOSURE CONFIGURED TO GRIP A CABLE SO AS TO LIMIT TENSION STRAIN ON THE CABLE

(71) Applicant: PPC BROADBAND, INC., East Syracuse, NY (US)

(72) Inventor: Nicholas B. LARSSON, Blomkest, MN (US)

(73) Assignee: PPC BROADBAND, INC., East Syracuse, NY (US)

(21) Appl. No.: 18/667,307

(22) Filed: May 17, 2024

Related U.S. Application Data
(60) Provisional application No. 63/502,995, filed on May 18, 2023.

(51) Int. Cl. F16L 5/02; H05K 5/02

(52) U.S. Cl. CPC F16L 5/02; H05K 5/0247

(57) ABSTRACT

A cable retainer for a port of an enclosure is configured to permit a pre-connectorized cable to be inserted into and removed from the port with a connector attached to the cable, including a cable retaining portion configured to receive a cable. The cable retaining portion comprises a cable receiving portion; the cable receiving portion comprises a cable engaging portion; the cable receiving portion is configured to align with an opening in a sealing portion so as to permit the cable to extend through both the cable receiving portion and the opening; and the cable engaging portion is configured to grip a cable that runs through a port such that the retainer limits axial movement of the cable relative to the port so as to limit tension strain on the cable.

### CROSS-REFERENCE TO RELATED APPLICATION

This application claims the benefit of U.S. Provisional Application No. 63/502,995 filed May 18, 2023, which is currently pending, the disclosure of which is hereby incorporated by reference herein in its entirety.

### BACKGROUND

The present disclosure relates generally to telecommunications enclosures and, in particular, to retaining a cable in a telecommunication enclosure such that strain on the cable is relieved while the cable is retained.

Some conventional sealing ports of cable enclosure boxes have a round opening through which a non-terminated cable end can be inserted and sealed via an interference fit between the seal and the cable. Then, after the cable end is inserted into the box, the cable end is terminated with a connector that is larger than the opening through the seal. Thus, in order to remove the cable from the box, the connector has to be removed usually by cutting the cable. The cable must then be terminated with a new connector after being reinserted into the enclosure box. All of this wastes the technician's time and the cost of multiple connectors.

Some conventional enclosure boxes, for example, fiber terminals, include closed cell foam grommet systems to provide lay-in cable sealing solutions. A lay-in solution refers to the ability to install pre-connectorized fiber cables without passing the connector end through the sealing surfaces. These lay-in slits in the foam grommet allow the mid-span of a cable to slide into the sealing positions and typically span a large portion of the overall grommet size, generally down the center of the grommet normal to the direction in which the grommet is compressed. While this arrangement allows for quick and easy installation of fiber cables it can be challenging to maintain a good seal. A soft or low durometer foam is best for forming a seal around the inserted cables. However, with a large slit through the center of the grommet, a soft material will not maintain its shape when cables are installed causing voids in the seal.

Some solutions for strain relief of distribution cables are one of two options which both take significant space within the enclosure. One option is traditional tie-down points using cable ties, ring clamps, etc., which, due to individual access requirements, can take significant space to support higher cable counts within the enclosure. The most common second option is a mandrel wrap style cable spool which, due to minimum bend radius requirements, also takes significant space within the enclosure.

Accordingly, it may be desirable to provide a retainer for a port of an enclosure that is configured to grip a cable that runs through the port such that the retainer limits axial movement of the cable relative to the port so as to limit tension strain on the cable. It may be desirable to provide a sealing system for a port of an enclosure that permits a pre-connectorized cable to be inserted into and removed from the port of the enclosure. Additionally or alternatively, it may be desirable to provide a sealing system with improved cable capacity. Additionally or alternatively, it may be desirable to provide a sealing system configured to maintain sealing consistency. Additionally or alternatively, it may be desirable to provide a compact sealing system that engages the cable to prevent movement of the cable within the sealing system and does not require a large amount of space inside the enclosure.

### SUMMARY

The present disclosure provides a much needed system for providing a seal between an enclosure and cables entering the enclosure, where a retainer engages an outer surface of the cable to prevent axial movement of the cable relative to the enclosure.

Embodiments of the disclosure include a cable port retainer that may be a modular clip that may be added to a multi-cable port seal. The retainer may have a U-shaped profile to support a lay-in cable installation and may align with the slots of the cable seal. The U-shaped profile may be designed to mate with the walls of the cable seal port in order to provide additional rigidity. The retainer may employ cable slots with openings smaller than a cable outer diameter and may be configured to flex to receive the cable jacket. Concentric ribs inside each cable slot may be configured to engage grooves on the cable jacket to provide tension strain relief normal to the cable axis. Embodiments support lay-in cable installations and align with cable slots in a port seal.

Embodiments provide a cable retainer for a port of an enclosure that is configured to permit a pre-connectorized cable to be inserted into and removed from the port with a connector attached to the cable, including: a sealing portion configured to be received in a seal receiving portion of a port; and a cable retaining portion configured to receive a cable. The sealing portion may comprise a resilient member; the sealing portion may be configured to include an opening that may be configured to receive a first portion of the cable; the opening may be configured to include a cross-sectional dimension that may be smaller than a connector that terminates the cable; the cable retaining portion is configured to be positioned adjacent to the sealing portion; the cable retaining portion may comprise a cable receiving portion; the cable receiving portion may comprise a cable engaging portion; the cable receiving portion may be configured to align with the opening so as to permit the cable to extend through both the cable receiving portion and the opening; the cable engaging portion may be configured to engage a circumferential slot in the cable; the cable engaging portion may comprise a protrusion that extends from the cable receiving portion; and the cable engaging portion may be configured to grip a cable that runs through the port such that the retainer limits axial movement of the cable relative to the port so as to limit tension strain on the cable.

In particular embodiments, the cable receiving portion may be configured to receive two cables.

In particular embodiments, the cable receiving portion may be structurally configured to receive both of the two cables through the same entry portion of the cable receiving portion.

In particular embodiments, the cable receiving portion may comprise a first cable holding portion that may be structurally configured to hold a first cable of the two cables in the cable receiving portion.

In particular embodiments, the cable receiving portion may be a first cable receiving portion, and the cable retainer may further comprise a second cable receiving portion.

In particular embodiments, the first cable receiving portion may be configured to receive two cables, and the second cable receiving portion may be configured to receive two cables.

In particular embodiments, the cable retaining portion may be structurally configured to be removed from an enclosure separately from the sealing portion.

In particular embodiments, the opening may be a first opening, the cable may be a first cable, and the sealing portion may further comprise a second opening that may be configured to receive a second cable.

In particular embodiments, the opening may be configured to be a slot in the sealing portion.

Embodiments provide a cable retainer for a port of an enclosure that is configured to permit a pre-connectorized cable to be inserted into and removed from the port with a connector attached to the cable, including a cable retaining portion configured to receive a cable. The cable retaining portion may be configured to be positioned adjacent to a sealing portion having an opening that may be configured to receive a first portion of the cable; the cable retaining portion may comprise a cable receiving portion; the cable receiving portion may comprise a cable engaging portion; the cable receiving portion may be configured to align with the opening so as to permit the cable to extend through both the cable receiving portion and the opening; and the cable engaging portion may be configured to grip a cable that runs through a port such that the retainer limits axial movement of the cable relative to the port so as to limit tension strain on the cable.

In particular embodiments, the cable engaging portion may be configured to engage a circumferential slot in the cable.

In particular embodiments, the cable engaging portion may comprise a protrusion that extends from the cable receiving portion.

In particular embodiments, the cable receiving portion may be configured to receive two cables.

In particular embodiments, the cable receiving portion may be structurally configured to receive both of the two cables through the same entry portion of the cable receiving portion.

In particular embodiments, the cable receiving portion may comprise a first cable holding portion that may be structurally configured to hold a first cable of the two cables in the cable receiving portion.

In particular embodiments, the cable receiving portion may be a first cable receiving portion, and the cable retainer may further comprise a second cable receiving portion.

Embodiments provide a cable retainer for a port of an enclosure that is configured to permit a pre-connectorized cable to be inserted into and removed from the port with a connector attached to the cable, including a cable retaining portion configured to receive a cable. The cable retaining portion may comprise a cable receiving portion; the cable receiving portion may comprise a cable engaging portion; the cable receiving portion may be configured to align with an opening in a sealing portion so as to permit the cable to extend through both the cable receiving portion and the opening; and the cable engaging portion may be configured to grip a cable that runs through a port such that the retainer limits axial movement of the cable relative to the port so as to limit tension strain on the cable.

In particular embodiments, the cable retaining portion may be configured to be positioned adjacent to the sealing portion.

In particular embodiments, the cable engaging portion may be configured to engage a circumferential slot in the cable.

In particular embodiments, the cable engaging portion may comprise a protrusion that may extend from the cable receiving portion.

In particular embodiments, the cable receiving portion may be configured to receive two cables.

In particular embodiments, the cable receiving portion may be structurally configured to receive both of the two cables through the same entry portion of the cable receiving portion.

In particular embodiments, the cable receiving portion may comprise a first cable holding portion that may be structurally configured to hold a first cable of the two cables in the cable receiving portion.

Various aspects of the system, as well as other embodiments, objects, features and advantages of this disclosure, will be apparent from the following detailed description of illustrative embodiments thereof, which is to be read in conjunction with the accompanying drawings.

### BRIEF DESCRIPTION OF THE DRAWINGS

FIG. 1 is a perspective view of a fiber enclosure including an exemplary seal assembly in accordance with various aspects of the disclosure.

FIG. 2 is an enlarged perspective view of the seal assembly of FIG. 1.

FIG. 3 is an enlarged perspective view of the seal assembly of FIG. 1.

FIG. 4 is a perspective view of the seal assembly of FIG. 1 showing a multi-cable port retainer in accordance with various aspects of the disclosure.

FIG. 5 is a front view of the multi-cable port retainer of FIG. 4.

FIG. 6 is a perspective view of a multi-cable port retainer in accordance with various aspects of the disclosure.

### DETAILED DESCRIPTION OF EMBODIMENTS

Embodiments of the disclosure provide a cable engaging portion that is configured to grip a cable that runs through a port of an enclosure such that the retainer limits axial movement of the cable relative to the port so as to limit tension strain on the cable.

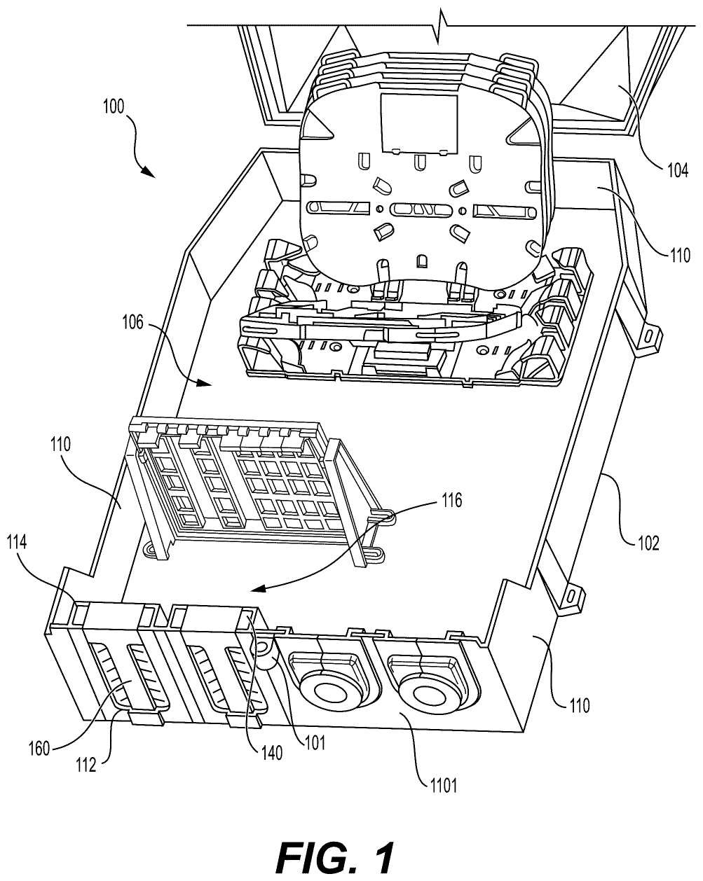

FIG. 1 illustrates an enclosure 100 that includes a base portion 102 defining a cavity and a cover portion 104 configured to be coupled with the base portion 102 to close the enclosure. In some aspects, the base portion 102 and the cover portion 104 may be configured to provide a sealed interface therebetween. The enclosure may include one or more electrical components, for example, fiber optic components 106 in the base portion 102. The base portion 102 may include a plurality of walls 110, 1101 and a port 112 configured to permit a cable, for example, an optical fiber cable, to pass therethrough. Although illustrated and described as a fiber enclosure, the enclosure may be any type of enclosure having a port for receiving a cable. Also shown in FIG. 1 is a receptacle, for example a threaded hole 101, configured to receive a fastener that secures the cover portion 104 to the base portion 102 in a closed position of the cover portion 104.

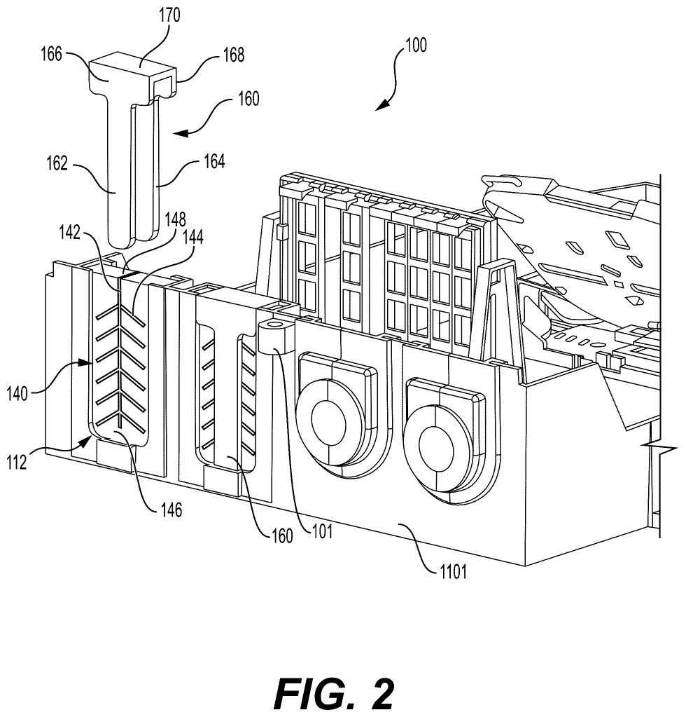

FIGS. 1-3 illustrate an exemplary seal assembly 116 for sealing the port 112 of the enclosure 100 in accordance with various aspects of the disclosure. The seal assembly 116 includes a reception portion, for example, a seal receiving portion, for example, a first body structure segment, 114, a first insert portion, for example, a sealing portion, 140, and a second insert portion, for example, a second body structure segment, 160. The reception portion 114, the first insert portion 140, and the second insert portion 160 are configured to seal the port 112.

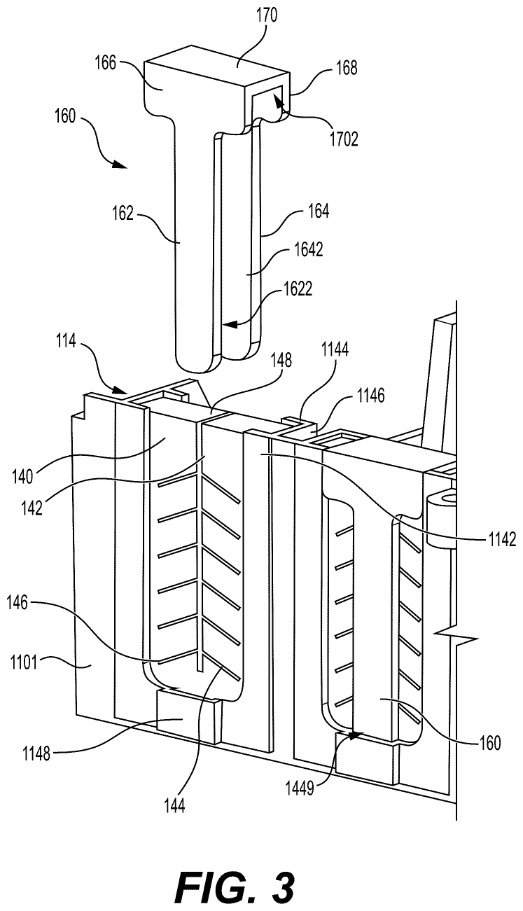

The reception portion 114 comprises a U-shaped channel that includes a first wall portion 1142, a second wall portion 1144, and a third wall portion 1146. The first and second wall portions 1142, 1144 are parallel to one another, and the third wall portion 1146 connects the first and second wall portions 1142 to form the U-shaped channel. As best shown in FIG. 3, the reception portion 114 comprises a U-shaped channel on each side of the port 112. The first wall portion 1142 may be an integral part of the wall 1101.

The first insert portion 140 may comprise a grommet, for example, a closed cell foam grommet. In embodiments, the first insert portion 140 includes an elongated slit or slot 142 extending from an end wall 148 of the first insert portion 140. The elongated slit 142 extends for a portion of a length of the first insert portion 140. The first insert portion 140 includes at least one opening, for example, a side slit or slot, for example, a first side slit or slot 144 or a second side slit or slot 146, extending from the elongated slit 142 for a portion of the distance to a side edge of the first insert portion 140 that extends parallel to the elongated slit 142. In embodiments, the side slit 144 or 146 extends away from the elongated slit 142 in a direction that is sloped away from the end wall 148 of the first insert portion 140. In some aspects, the first insert portion 140 may include both the first side slit 144 extending from one side of the elongated slit 142 and the second side slit 146 extending from an opposite side of the elongated slit 142. In some aspects, the first insert portion 140 may include a plurality of the first side slits 144 and/or a plurality of the second side slits 146.

FIG. 3 shows an embodiment of the second insert portion 160, for example, a support or bracket portion, that may comprise a T-shape having two elongated arm portions 162, 164 and two short arm portions 166, 168 that extend perpendicular to the elongated arm portions 162, 164. The two short arm portions 166, 168 have a length that substantially matches the distance between the two U-shaped channels of the receiving portion 114. The two short arm portions 166, 168 are connected by a transverse portion 170. In this example, the two elongated arm portions 162, 164 are spaced apart from one other by a distance, and the two short arm portions 166, 168 are spaced apart from one other by the same distance. The distance is determined by the dimension of the transverse portion 170 that extends between the short arm portions 166, 168. The first elongated arm portion 162 and the first short arm portion 166 define a first inner surface 1622, and the second elongated arm portion 164 and the second short arm portion 168 define a second inner surface 1642. The transverse portion 170 includes an inner surface 1702 that faces in a direction in which the elongated arms 162, 164 extend.

In use, the first insert portion 140 is inserted into an open end of the receiving portion 114. The first insert portion 140 may comprise a compressible material, for example, a closed cell foam, such that a thickness of the first insert portion 140 may be greater than the width of the U-shaped channel between the first wall portion 1142 and the second wall portion 1144 such that the first insert portion 140 is compressed between the first wall portion 1142 and the second wall portion 1144. A cable, for example, a pre-connectorized fiber cable, is inserted into the elongated slit 142 and into one of the side slits 144, 146. The second insert portion 160 is then inserted into the receiving portion 114 until the short arm portions 166, 168 are between the first wall portion 1142 and the second wall portion 1144 of the U-shaped channels of the receiving portion 114, the inner surface 1702 of the transverse portion 170 engages the end wall 148 of the first insert portion 140, and free ends of the elongated arm portions 162, 164 are received in a receiving portion such as, for example, a notch 1148 at a bottom portion of the wall 1101.

After such insertion, the second insert portion 160 is configured to compress the first insert portion 140 in two directions. For example, the transverse portion 170 engages the end wall 148 to compress the first insert portion 140 in an insertion direction and in a second direction between the two inner surfaces 1622, 1642 of the second insert portion 164.

To remove the cable, the second insert portion 160 is removed, and the cable is slid out from the side slit 144, 146 into the elongated slit 142 and then out of the elongated slit 142. The procedure of inserting and removing the cable can be repeated as often as needed. As a result, a pre-connectorized cable, for example, a pre-connectorized fiber cable, can be inserted into and removed from the seal assembly as often as desired without the need for removing the connector from the cable.

It should be understood that when the fiber is inserted into the side slit 144, 146, the fiber does not impede placement of the second insert portion 160 between the first wall portion 1142 and the second wall portion 1144 of the U-shaped channels of the receiving portion 114.

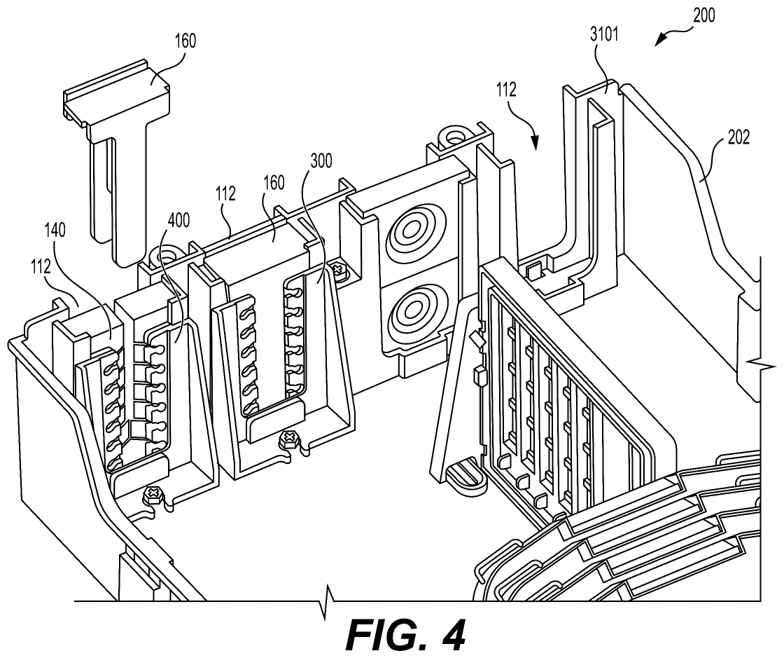

FIG. 4 shows two cable retaining portions, for example, port retainers, 300, 400, each located inside of a base portion 202 of an enclosure 200. Similarly to the enclosure 100 of FIGS. 1-3, the enclosure 200 has a plurality of ports 112 in a wall 3101. The port retainers 300, 400 are configured to engage a cable that pass through the first insert portion 140 so that movement of the cable in a direction into or out of the enclosure 200 is limited, or completely prevented.

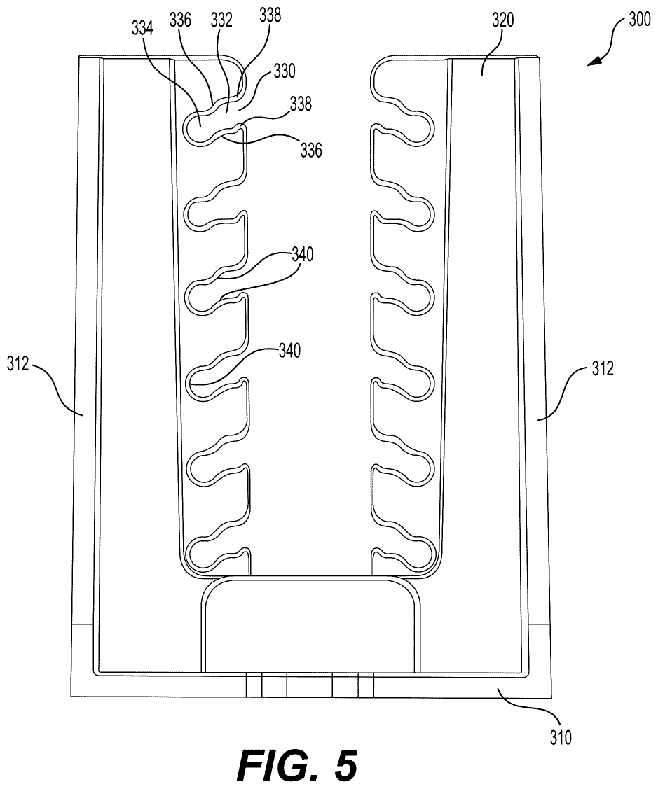

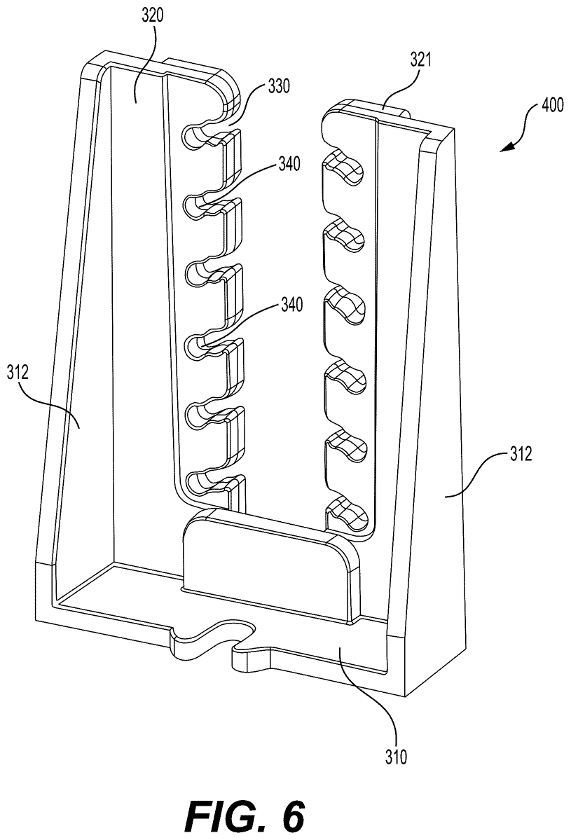

FIG. 5 shows port retainer 300 which is, in this example, configured to engage cables with an outer diameter of 3 mm. FIG. 6 shows port retainer 400 which is, in this example, configured to engage cables with an outer diameter of 2 mm. These two cable sizes are shown as examples only. The port retainer may be sized to fit any desired cable size. The features of the port retainer 300 and the port retainer 400 are the same except for the size of cable they are design to receive.

As shown in FIG. 5, this example of the port retainer 300 has two side walls 312 that are joined by a bottom wall 310. A main portion 320 extends between the side walls 312 and the bottom wall 310. In this example, the main portion 320 includes a reinforcing portion 321 that is attached to, or is an integrally formed part of, the main portion 320. In this example, the port retainer 300 has at least one cable receiving portion 330 in the main portion 320 that is configured to receive one or more cables. In this example, the cable receiving portion 330 has two cable holding portions, for example, cable receiving areas, 332, 334. A cross-sectional size and shape of each of the cable receiving areas 332, 334 is configured to receive a certain size cable (for example, 3 mm). For example, the cable receiving areas 332, 334 may be circular to receive a cable having a circular cross-section. The cable receiving areas 332, 334 align with the side slits 144, 146 in the first insert portion 140.

In the example shown in FIG. 5, the cable receiving areas 332, 334 have protrusions 336, 338 that partially define the shape of the cable receiving areas 332, 334. In this example, the cable receiving portion 330 is configured to receive and hold two cables. However, in other embodiments, the cable receiving portion 330 is configured to receive fewer or more than two cables.

As best shown in FIG. 6, the cable receiving portion 330 may include a cable engaging portion such as, for example, a rib portion, for example, a rib, 340 that extends from the main portion 320 (and/or from the reinforcing portion 321) into the cable receiving portion 330. The rib portion 340 may extend into the cable receiving portion 330 along the entire perimeter of the cable receiving portion 330, as shown in FIGS. 5 and 6, or it may extend into the cable receiving portion 330 along less than the entire perimeter of the cable receiving portion 330. For example, the rib portion 340 may include a plurality of rib sections that extend into the cable receiving portion 330.

The rib portion 340 is configured to engage a cable receiving area engaging portion of a cable such as, for example, a circumferential slot or a groove in an exterior surface of a cable. For example, a cable may have an outer surface that includes a plurality of circumferential parallel grooves that allow the cable to be more flexible than if the outer surface had no grooves. In embodiments, the rib portion 340 is configured to engage (for example, fit into) one of the grooves on the cable. By engaging one of the grooves in the cable, the rib 340 limits (or prevents) the cable from moving relative to the rib portion 340 and, therefore, relative to the port retainer 300. By limiting or preventing this relative movement, the port retainer 300 limits or prevents tension strain on the portion of the cable inside (and the portion outside) the enclosure 100, 200. This tension strain prevention is beneficial to prevent a connector, splice, or other termination of the cable from being subjected to pulling (or pushing) forces that could damage the termination.

In embodiments the cable receiving portion 330 is open at one end so that it is configured to receive a cable at any point along the cable without having to remove a connector or other feature that is attached to the end of the cable. In embodiments, the cable receiving areas 332, 334 are sized to be smaller than the outer size of the cable so that the cable jacket compresses in the receiving area 332, 334 to help retain the cable in the cable receiving area 332, 334. Although both port retainer 300 and port retainer 400 are shown being configured to receive cables of a certain size, it is noted that one port retainer can be configured to hold a first size cable in the cable receiving area 332 and a different size cable in the cable receiving area 334.

In embodiments, the port retainer 300, 400 being secured to the enclosure 100, 200 in a position where it contacts the port 112 and/or the reception portion 114 adds rigidity to the wall 1101, 3101.

Although the example in FIG. 4 shows the port retainers 300, 400 mounted inside the enclosure 200, in other embodiments, the port retainer Is configured to be mounted to an outside of the enclosure.

Although the illustrative embodiments of the present invention have been described herein with reference to the accompanying drawings, it is to be understood that the invention is not limited to those precise embodiments, and that various other changes and modifications may be effected therein by one skilled in the art without departing from the scope or spirit of the invention.

Various changes to the foregoing described and shown structures will now be evident to those skilled in the art. Accordingly, the particularly disclosed scope of the invention is set forth in the following claims.

What is claimed is:

1. A cable retainer for a port of an enclosure that is configured to permit a pre-connectorized cable to be inserted into and removed from the port with a connector attached to the cable, comprising:
a sealing portion configured to be received in a seal receiving portion of a port;
a cable retaining portion configured to receive a cable;
wherein the sealing portion comprises a resilient member;
wherein the sealing portion is configured to include an opening that is configured to receive a first portion of the cable;
wherein the opening is configured to include a cross-sectional dimension that is smaller than a connector that terminates the cable;
wherein the cable retaining portion is configured to be positioned adjacent to the sealing portion;
wherein the cable retaining portion comprises a cable receiving portion;
wherein the cable receiving portion comprises a cable engaging portion;
wherein the cable receiving portion is configured to align with the opening so as to permit the cable to extend through both the cable receiving portion and the opening;
wherein the cable engaging portion is configured to engage a circumferential slot in the cable;
wherein the cable engaging portion comprises a protrusion that extends from the cable receiving portion;
wherein the cable engaging portion is configured to grip a cable that runs through the port such that the retainer limits axial movement of the cable relative to the port so as to limit tension strain on the cable.

2. The cable retainer of claim 1, wherein the cable receiving portion is configured to receive two cables.

3. The cable retainer of claim 2, wherein the cable receiving portion is structurally configured to receive both of the two cables through the same entry portion of the cable receiving portion.

4. The cable retainer of claim 1, wherein the cable receiving portion comprises a first cable holding portion that is structurally configured to hold a first cable of the two cables in the cable receiving portion.

5. The cable retainer of claim 1, wherein the cable receiving portion is a first cable receiving portion, and the cable retainer further comprises a second cable receiving portion.

6. The cable retainer of claim 5, wherein the first cable receiving portion is configured to receive two cables, and the second cable receiving portion is configured to receive two cables.

7. The cable retainer of claim 1, wherein the cable retaining portion is structurally configured to be removed from an enclosure separately from the sealing portion.

8. The cable retainer of claim 1, wherein the opening is a first opening, the cable is a first cable, and the sealing portion further comprises a second opening that is configured to receive a second cable.

9. The cable retainer of claim 1, wherein the opening is configured to be a slot in the sealing portion.

10. A cable retainer for a port of an enclosure that is configured to permit a pre-connectorized cable to be inserted into and removed from the port with a connector attached to the cable, comprising:
a cable retaining portion configured to receive a cable;
wherein the cable retaining portion is configured to be positioned adjacent to a sealing portion having an opening that is configured to receive a first portion of the cable;
wherein the cable retaining portion comprises a cable receiving portion;
wherein the cable receiving portion comprises a cable engaging portion;
wherein the cable receiving portion is configured to align with the opening so as to permit the cable to extend through both the cable receiving portion and the opening; and
wherein the cable engaging portion is configured to grip a cable that runs through a port such that the retainer limits axial movement of the cable relative to the port so as to limit tension strain on the cable.

11. The cable retainer of claim 10, wherein the cable engaging portion is configured to engage a circumferential slot in the cable.

12. The cable retainer of claim 10, wherein the cable engaging portion comprises a protrusion that extends from the cable receiving portion.

13. The cable retainer of claim 10, wherein the cable receiving portion is configured to receive two cables.

14. The cable retainer of claim 13, wherein the cable receiving portion is structurally configured to receive both of the two cables through the same entry portion of the cable receiving portion.

15. The cable retainer of claim 10, wherein the cable receiving portion comprises a first cable holding portion that is structurally configured to hold a first cable of the two cables in the cable receiving portion.

16. The cable retainer of claim 10, wherein the cable receiving portion is a first cable receiving portion, and the cable retainer further comprises a second cable receiving portion.

17. A cable retainer for a port of an enclosure that is configured to permit a pre-connectorized cable to be inserted into and removed from the port with a connector attached to the cable, comprising:
a cable retaining portion configured to receive a cable;
wherein the cable retaining portion comprises a cable receiving portion;
wherein the cable receiving portion comprises a cable engaging portion;
wherein the cable receiving portion is configured to align with an opening in a sealing portion so as to permit the cable to extend through both the cable receiving portion and the opening; and
wherein the cable engaging portion is configured to grip a cable that runs through a port such that the retainer limits axial movement of the cable relative to the port so as to limit tension strain on the cable.

18. The cable retainer of claim 17, wherein the cable retaining portion is configured to be positioned adjacent to the sealing portion.

19. The cable retainer of claim 17, wherein the cable engaging portion is configured to engage a circumferential slot in the cable.

20. The cable retainer of claim 17, wherein the cable engaging portion comprises a protrusion that extends from the cable receiving portion.

21. The cable retainer of claim 17, wherein the cable receiving portion is configured to receive two cables.

22. The cable retainer of claim 21, wherein the cable receiving portion is structurally configured to receive both of the two cables through the same entry portion of the cable receiving portion.

23. The cable retainer of claim 17, wherein the cable receiving portion comprises a first cable holding portion that is structurally configured to hold a first cable of the two cables in the cable receiving portion.
